(19) United States
(12) Patent Application Publication
(10) Pub. No.: US 2012/0325305 A1
(43) Pub. Date: Dec. 27, 2012

(54) OHMIC CONTACT BETWEEN THIN FILM SOLAR CELL AND CARBON-BASED TRANSPARENT ELECTRODE

(75) Inventors: BHUPESH CHANDRA, Jersey City, NJ (US); Augustin J. Hong, White Plains, NY (US); Jeehwan Kim, Los Angeles, CA (US); Devendra K. Sadana, Pleasantville, NY (US); George S. Tulevski, White Plains, NY (US)

(73) Assignee: INTERNATIONAL BUSINESS MACHINES CORPORATION, ARMONK, NY (US)

(21) Appl. No.: 13/165,216

(22) Filed: Jun. 21, 2011

(51) Int. Cl. H01L 31/0224; H01L 31/18; B82Y 99/00; B82Y 40/00

(52) U.S. Cl. 136/256; 438/87; 977/948; 977/742; 977/734; 977/773; 257/E31.011; 257/E31.039

(57) ABSTRACT

A photovoltaic device and method include a photovoltaic stack having an N-doped layer, a P-doped layer and an intrinsic layer. A transparent electrode is formed on the photovoltaic stack and includes a carbon based layer and a high work function metal layer. The high work function metal layer is disposed at an interface between the carbon based layer and the P-doped layer such that the high work function metal layer forms a reduced barrier contact and is light transmissive.

### RELATED APPLICATION DATA

This application is related to commonly assigned application Ser. No. 12/776,549, entitled, “HIGH WORK FUNCTION METAL INTERFACIAL FILMS FOR IMPROVING FILL FACTOR IN SOLAR CELLS,” (Attorney Docket Number (YOR920100235US1 (163-344)), filed May 10, 2010 and incorporated herein by reference.

### BACKGROUND

1. Technical Field

The present invention relates to photovoltaic devices, and more particularly to devices and methods for improving performance by reducing barriers for carbon-based electrodes.

2. Description of the Related Art

Solar cells employ photovoltaic cells to generate current flow. Photons in sunlight hit a solar cell or panel and are absorbed by semiconducting materials, such as silicon. Carriers gain energy allowing them to flow through the material to produce electricity. Therefore, the solar cell converts the solar energy into a usable amount of electricity.

When a photon hits a piece of silicon, the photon may be transmitted through the silicon, the photon can reflect off the surface, or the photon can be absorbed by the silicon, if the photon energy is higher than the silicon band gap value. This generates an electron-hole pair and sometimes heat, depending on the band structure.

When a photon is absorbed, its energy is given to a carrier in a crystal lattice. Electrons in the valence band may be excited into the conduction band, where they are free to move within the semiconductor. The bond that the electron(s) were a part of form a hole. These holes can move through the lattice creating mobile electron-hole pairs.

A photon need only have greater energy than that of a band gap to excite an electron from the valence band into the conduction band. Since solar radiation is composed of photons with energies greater than the band gap of silicon, the higher energy photons will be absorbed by the solar cell, with some of the energy (above the band gap) being turned into heat rather than into usable electrical energy.

A solar cell may be formed on a glass substrate or metal substrate and includes an electrode separated from a p-type layer where a Schottky or contact barrier forms at the interface. The electrode includes a transparent thin film that is conductive or a transparent conductive oxide (TCO). Generally, such films include material like ZnO:Al, which must be vacuum-deposited and requires expensive equipment. These materials tend to be brittle and not compatible with flexible substrates. Currently developed TCOs are n-type since p-type states of TCO are thermodynamically unstable. Therefore, a Schottky barrier exists between the p-type layer and the TCO. The Schottky barrier is a potential barrier formed at a metal-semiconductor junction which has rectifying characteristics like a diode. The formation of the Schottky barrier is difficult to avoid and overcome. The barrier forms as a result of the materials in contact (N-type metal and P-type semiconductor). Due to the N-type nature of TCO, the Schottky barrier always exists at the interface between the P-type semiconductor and TCO.

The Schottky barrier increases series resistance by reducing the slope of a current density versus voltage (J-V) curve of a pin diode. This accounts for a large portion of fill factor (FF) degradation, where the FF describes the efficiency of a solar cell. FF is a ratio of the maximum power point (Pₘ) divided by open circuit voltage (V_{oc}) and short circuit current (J_{sc}):

$$FF = \frac{{P}_{m}}{{V}_{oc} {J}_{sc}} .$$

When the carbon electrodes are used as a transparent electrode, the Schottky barrier problem is supposed to be reduced in theory since the work function of the carbon electrode (4.7-5.2 eV) is significantly higher than that of a typical TCO. However, in practice, when carbon is disposed on the p-type a-Si:H, the Schottky barrier problem becomes more severe. This may be due to Fermi level pinning or unknown compound formation at the carbon/p+ a-Si:H interface.

### SUMMARY

A photovoltaic device and method include a photovoltaic stack having an N-doped layer, a P-doped layer and an intrinsic layer. A transparent electrode is formed on the photovoltaic stack and includes a carbon based layer and a high work function metal layer. The high work function metal layer is disposed at an interface between the carbon based layer and the P-doped layer such that the high work function metal layer forms a reduced barrier contact and is light transmissive.

Another photovoltaic device includes a photovoltaic stack having a P-type layer, an intrinsic layer and an N-type layer and a transparent electrode formed on the P-type layer of the photovoltaic stack. The transparent electrode includes a conductive carbon based layer and a high work function metal layer. The high work function metal layer is disposed at an interface between the carbon based layer and the P-type layer such that the high work function metal layer forms a reduced barrier contact and is light transmissive. A reflective metal substrate is disposed in contact with the N-type layer.

A method for forming a photovoltaic device includes forming a photovoltaic stack on a first electrode, the stack including an N-type layer, an intrinsic layer and a P-type layer; depositing a high work function metal layer on the photovoltaic stack; and forming a carbon based layer over the high work function metal layer such that the carbon based layer and the high work function metal layer form a reduced barrier contact that is light transmissive.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a cross-sectional view of a photovoltaic device having a high work function metal layer with a carbon-based layer to from a transparent electrode and to reduce effects due to the formation of a Schottky barrier in accordance with the present principles;

FIG. 2 is a plot of current density versus voltage showing that devices using a transparent carbon electrode are non-operational due to Schottky barrier formation;

FIG. 3 is a plot of current density versus voltage showing improved current density as a result of a high work function metal layer in accordance with the present principles;

FIGS. 4A-4F show an illustrative process for forming a carbon transparent electrode (CTE) using high work function nanodots in accordance with one illustrative embodiment; and

FIG. 5 is a block/flow diagram showing a method for fabricating a photovoltaic device with a high work function metal layer and a carbon-based layer in accordance with the present principles.

### DETAILED DESCRIPTION OF PREFERRED EMBODIMENTS

In accordance with the present principles, devices and methods are provided which reduce the effects of Schottky barrier degradation and permit the use of less expensive materials and processes without sacrificing device performance. In one embodiment, carbon based material is employed instead of a transparent conductive oxide. Carbon based materials are inexpensive, easily processable with inexpensive processes and are compatible with flexible substrates. The carbon based electrode preferably includes a high work-function metal as an interlayer (e.g., between the electrode and a p-type layer of an adjacent n-i-p stack). The high work function layer modifies the interlayer interface to create an ohmic contact. The high work function layer may include metal dots (e.g., nanodots). In this way, the Schottky barrier on the interlayer interface is reduced.

It is to be understood that the present invention will be described in terms of a given illustrative architecture; however, other architectures, structures, substrate materials and process features and steps may be varied within the scope of the present invention.

It will also be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A design for an integrated circuit chip of photovoltaic device may be created in a graphical computer programming language, and stored in a computer storage medium (such as a disk, tape, physical hard drive, or virtual hard drive such as in a storage access network). If the designer does not fabricate devices or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips or photovoltaic devices. The resulting devices can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips/devices, ranging from toys and other low-end applications to advanced computer products having a display, a keyboard or other input device, and a central processor.

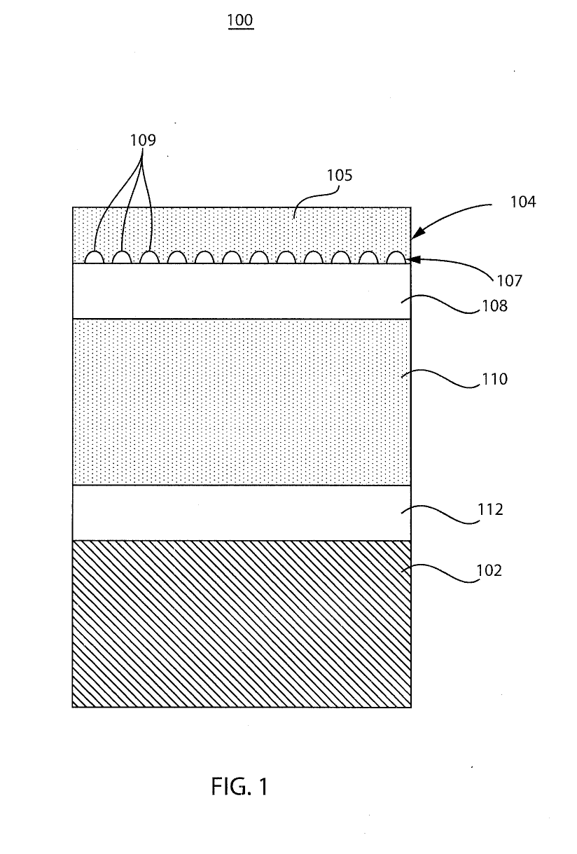

Referring now to the drawings in which like numerals represent the same or similar elements and initially to FIG. 1, an illustrative photovoltaic structure 100 is illustratively depicted in accordance with one embodiment. The photovoltaic structure 100 may be employed in solar cells, light sensors or other photovoltaic applications, including devices with flexible substrates. Structure 100 may include different materials. In the present embodiment, the structure 100 includes an amorphous silicon cell disposed between two electrodes. One electrode may include a metal substrate 102. The metal substrate 102 may include a reflective material or surface to permit incident radiation to reflect back to the absorption layers formed in contact with the metal substrate 102. The substrate 102 may be employed to enable a flexible solar cell device. Another electrode 104 includes a carbon based material 105 and a high work function layer 107. In a conventional device, the electrode 104 may include a transparent conductive oxide, such as ZnO, indium tin oxide (ITO) or the like. The electrode 104 preferably includes the carbon based materials such as carbon nanotubes (CNT) or graphene. The electrode 104 permits light to pass through to an active light-absorbing material beneath and allows conduction to transport photo-generated charge carriers away from that light-absorbing material. The carbon based electrode 104 is less reactive and more durable than other electrode materials and is more advantageous for use with flexible solar panels or devices.

The light-absorbing material includes a P-type layer 108, such as P+ doped amorphous silicon (a-Si) or hydrogenated amorphous silicon (a-Si:H) although other materials may be employed. In this illustrative structure 100, layer 107 is formed on the P-type layer 108. In this way, layer 107 may be formed as metal nanodots 109. The nanodots 109 may include high work function metals, such as Au, Pd, Ag, Pt or the like.

An intrinsic layer 110 of compatible material is formed in contact with layer 108. Intrinsic layer 110 is preferably undoped and may include amorphous silicon (a-Si) or hydrogenated amorphous silicon (a-Si:H). An N-type layer 112 is formed in contact with the intrinsic layer 110. The N-type layer 112 may include an N+ doped amorphous silicon (a-Si) or hydrogenated amorphous silicon (a-Si:H). The N-type layer 112 is in contact with the back-reflector metal substrate 102. The back-reflector substrate 102 may be in contact with a second additional back-reflector (not shown). It should be understood that other structures, materials and layers may also be employed to complete fabrication of the device 100.

It should be noted that the structure may be inverted or may include P and N-type regions reversed along with the reversal of other structures for proper operation with a transparent substrate.

The structure 100 is preferably a silicon thin-film cell, which includes silicon layers which may be deposited by a chemical vapor deposition (CVD) process or a plasma-enhanced (PE-CVD)) from silane gas and hydrogen gas. Depending on the deposition parameters, amorphous silicon (a-Si or a-Si:H), and/or nanocrystalline silicon (nc-Si or nc-Si:H) or microcrystalline silicon may be formed. The layers 108 and 112 and intrinsic layer 110 may include other materials and material combinations.

In one embodiment, layer 107 is formed between carbon-based material 105 and layer 108 to avoid the formation of a diode-like Schottky barrier. In one embodiment, nanodots are formed as a layer 107 between material 105 and layer 108 (which may include P-type a-Si:H).

In accordance with the present principles, the contact barrier problem is reduced or avoided by providing layer 107 with a high work function (e.g., highly conductive) material. These types of materials are highly reflective and would reduce the absorption of radiation that is needed in a solar collector. The high work function metal, such as, Au, Pd, Ag, Pt, etc. or combinations thereof may be made ultra-thin or as an intermittent pattern (e.g., nanodots). The layer 107 can be made thin enough or sparsely enough to avoid transmittance loss. For example, layer 107 may include a metal layer of between about 0.1 nm and 20 nm. The metal layer 107 is preferably a P-type metal although N-type metals may also be employed. By forming layer 107 from an ultra-thin high work function conductor, a direct removal or reduction of any contact barrier is achieved. High work function may be defined as a work function higher than a work function of the carbon based material 105 and close to the valence band edge of the P-type layer 108. For example, in preferred embodiments the high work function may be greater than about 5 or 6 eV.

Layer 107 may include a non-continuous layer of material. In one example, the ultra-thin metal may include nanodots 109. Nanodots can naturally occur under particular process conditions such as during an evaporation process where the thickness is sufficiently thin. Nanodots have a characteristic size of less than 10 nm, and more preferably less than about 2 nm. When the metals form discontinuous dots, more current is permitted to flow than for solar cells without a metal layer 107. The nanodots promote a plasmonic light trapping effect to assist in increasing current.

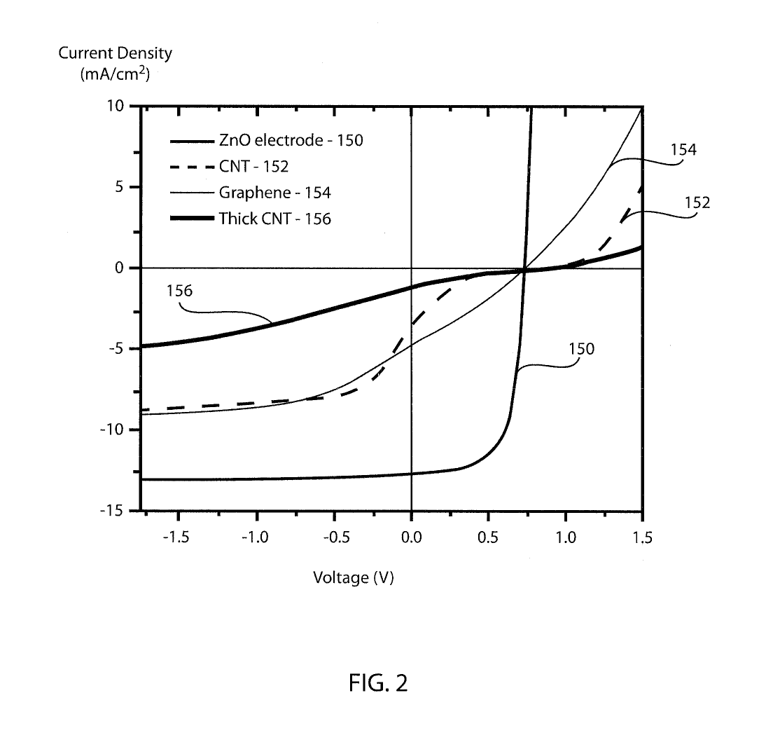

Normally, a contact/electrode 106 is a transparent conductive oxide (TCO), which permits light to transit therethrough. In accordance with one illustrative embodiment, the carbon based layer 105 and the non-transparent metal interlayer 107 are employed to form an ohmic contact or to reduce a Schottky barrier between the metal contact and the semiconductor material. The non-transparent metal is formed in a layer that may include dots, nanodots or is so thin (ultra-thin) that light can still be transmitted through it and extra current due to plasmonic light trapping is provided. The ohmic contact reduces or eliminates any Schottky effect or barrier hence improving the fill factor (FF). The metal layer 107 improves the fill factor as well as short circuit current. It should be noted that employing the carbon based layer 105 without the metal layer 107 results in an increased Schottky barrier as will be described with respect to FIG. 2.

Referring to FIG. 2, current density is plotted versus voltage for a solar cell structure having a plurality of different materials for an upper electrode (106) without a high work function layer (107) to demonstrate benefits in accordance with the present principles. In plot 150, a transparent conductive oxide (ZnO) is shown as a control sample for comparison with plots 152, 154, 156 for carbon based materials. Plot 152 includes a carbon nanotube (CNT) layer without a high work function metal. Plot 154 includes a graphene layer without a high work function metal. Plot 156 includes a thick CNT layer without a high work function metal. The plots 152, 154 and 156 of cells with carbon based electrodes without a high work function material show these cells are non-operational as compared to the ZnO electrode of ploy 150. The plots 152, 154 and 156 demonstrate that when carbon is disposed on the p-type a-Si:H, the Schottky barrier problem becomes severe due to, e.g., Fermi level pinning or unknown compound formation at the carbon/p+ a-Si:H interface. As such, these cells cannot properly function as solar cells.

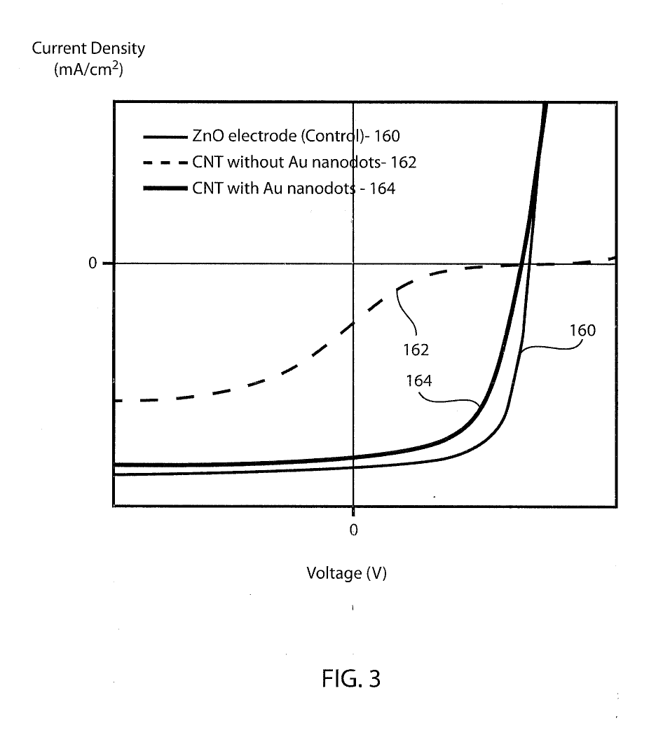

Referring to FIG. 3, current density is plotted versus voltage for a solar cell structure having a CNT electrode without a high work function metal layer (plot 162) and a CNT electrode with a layer of gold nanodots (plot 164) in accordance with the present principles. A control plot 160 for a ZnO electrode is also shown. As can be seen from the plots 162 and 164, current density increases dramatically with voltage when the high work function metal layer is present. Further, the plot 162 with CNT alone is non-operational. In addition, the plot 164 for an embodiment in accordance with the present principles performed comparably or better than the control plot 160 (with a ZnO electrode).

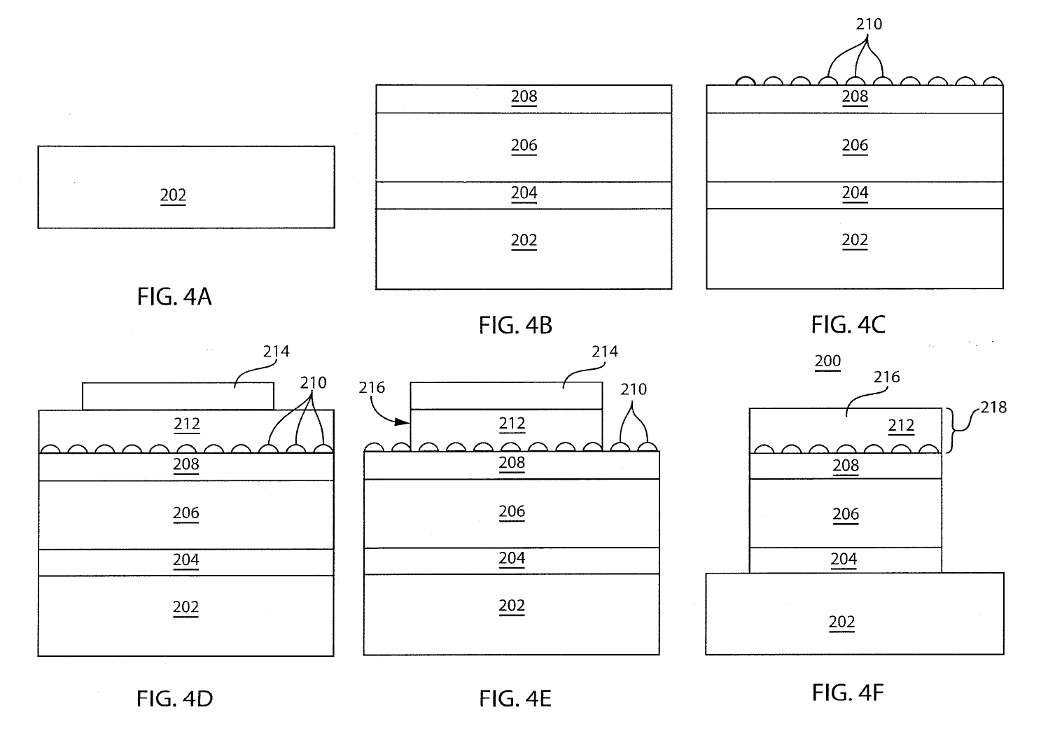

Referring to FIGS. 4A-4F, an illustrative process for forming a photovoltaic device with a carbon transparent electrode (CTE) is shown. It should be understood that the materials described herein may include variations or completely different materials from those illustratively described. In FIG. 4A, a metal substrate 202 is provided. The metal substrate 202 may include, e.g., Al, Ti, W, etc. The metal substrate 202 may be flexible for providing a flexible solar cell in accordance with one embodiment. In FIG. 4B, an N+ doped layer of hydrogenated amorphous silicon 204 is deposited on the metal substrate 202. An intrinsic layer 206 of hydrogenated amorphous silicon is formed on layer 204. A P+ doped layer of hydrogenated amorphous silicon 208 is deposited on the intrinsic layer 206. The n-i-p (or p-i-n) stack including layers 204, 206 and 208 may be deposited using a chemical vapor deposition (CVD) process, a plasma enhanced CVD (PECVD) process, etc.

In FIG. 4C, a deposition process is performed to form nanodots 210 on layer 208. The deposition process may include a CVD process or the like to form metal dots having a size of between about 0.1 nm to about 20 nm, and more preferably between about 0.5 nm and 2 nm. The nanodots form a high work function metal layer that may include one or more of Au, Pd, Ag, Pt, their alloys, etc. In FIG. 4D, a carbon based layer 212 is formed over the dots 210.

Carbon based conductive material 212 may include carbon nanotubes, graphene, or other carbon based conductive structures. The carbon based layer 212 is transparent. Carbon nanotubes may be deposited using CNT solution processing (dip coating), vacuum filtration, chemical vapor deposition (CVD), plasma enhanced CVD, etc. During CVD, a layer of metal catalyst is preferably employed. The catalysts may include particles, which may be formed on the nanodots 210 and on layer 208 or the nanodots 210 themselves may be employed in growing the carbon nanotubes. The particles formed on the nanodots 210 may include nickel, cobalt, iron, or a combination thereof. The metal particles may be produced in other ways, including reduction of oxides or oxides solid solutions. The diameters of the nanotubes that are to be grown are related to the size of the metal particles. This can be controlled by annealing, by plasma etching metal, etc. Carbon nanotube growth is provided in a heated environment (e.g., approximately 700° C.). To initiate the growth of the carbon nanotubes, two gases are bled into a reactor. The two gases include a process gas (such as, e.g., ammonia, nitrogen or hydrogen) and a carbon-containing gas (such as, e.g., acetylene, ethylene, ethanol or methane). Carbon nanotubes grow at the sites of the metal catalyst particles. The carbon-containing gas is broken down at the surface of the particles where it forms the nanotubes. If PECVD is employed, an electric field during the growth process dictates the direction of carbon nanotube growth.

Highly transparent graphene films may also be formed by a solution process or chemical vapor deposition. In this process, an ultra-thin graphene sheet may be formed by first depositing carbon atoms (from, e.g., methane gas) in the form of graphene films on a catalyst (e.g., nanodot metal or additional metal particles (such as nickel)). Graphene may also be formed usual epitaxial growth processes. A mask 214 is formed on the layer 210 which will be employed in later steps for isolating cells on the metal substrate 202.

In FIG. 4D, the mask is employed to etch away part of the carbon based layer 212 to form a carbon electrode 216. The etching process may include an O₂ plasma etch to define a device area for a solar cell to be fabricated. In FIG. 4F, the remaining layers 208, 206, 204 as well as dots 210 outside of the mask 214 are etched down to the metal substrate 202 to isolate a cell or cells for forming a solar device 200 and, in particular, a flexible solar device. The mask 214 is removed from the carbon electrode 216. The solar device 200 now includes a transparent carbon electrode (TCE) 218 that includes a high work function material (210). The solar device 200 may be configured to flex at the metal substrate 202 (e.g., acting as hinges between cells). The cells are isolated (spaces formed between them) to permit deflection of the metal substrate 202.

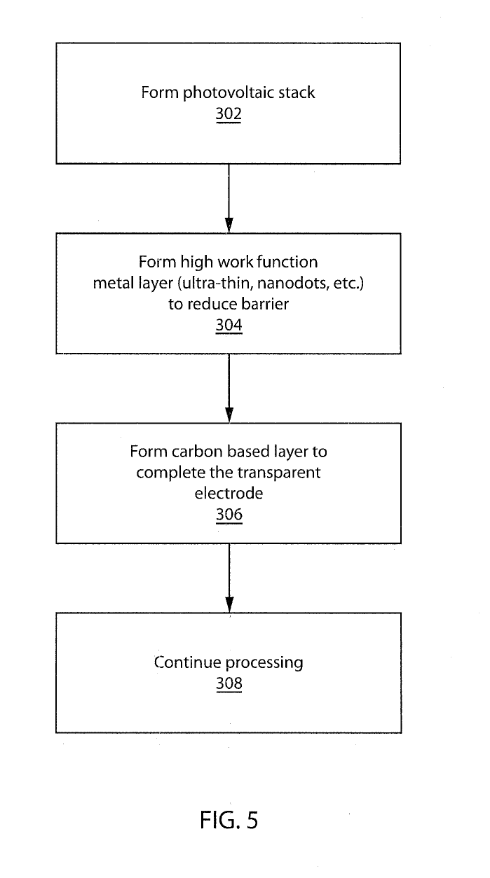

Referring to FIG. 5, a block/flow diagram shows a method for forming a photovoltaic device in accordance with the present principles. It should also be noted that, in some implementations as depicted in FIG. 5, the functions noted in the blocks may occur out of the order noted in the FIGS. For example, two blocks shown in succession may, in fact, be executed substantially concurrently, or the blocks may sometimes be executed in the reverse order, depending upon the functionality involved.

In block 302, a photovoltaic stack is formed on a first electrode. The stack includes a P-type layer, an N-type and an intrinsic layer. The doped layers may include amorphous silicon or other materials, such as e.g., SiC, etc. The first electrode may include a substrate on which the device is assembled, for example, a metal substrate. In a particularly useful embodiment, the first electrode is reflective to reflect light to enhance absorption of radiation by the stack. In another useful embodiment, the first electrode is a flexible substrate.

In block 304, a high work function metal layer is deposited on the photovoltaic stack. The high work function metal may include one or more of Au, Ag, Pd, Pt, their alloys, etc. The high work function metal layer may be deposited using a chemical vapor deposition (CVD) process, a plasma enhanced CVD (PECVD) process, atomic layer deposition (ALD) or any other suitable method capable of forming an ultra-thin metal layer or discontinuous metal layer (e.g., dots or nanodots).

In block 306, a carbon based layer is formed over the high work function metal layer such that the carbon based layer and the high work function metal layer form a reduced barrier contact that is light transmissive. The carbon based layer may include one of carbon nanotubes, graphene or other conductive carbon structure. The reduced barrier contact may form an ohmic contact.

In block 308, further processing may be performed. For example, additional layers or cells may be added to the device, protective layers may be added, isolated cells may be formed (e.g., for a flexible device), etc.

Having described preferred embodiments of a ohmic contact between thin film solar cell and carbon-based transparent electrode (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A photovoltaic device, comprising:
a photovoltaic stack having an N-doped layer, a P-doped layer and an intrinsic layer; and
a transparent electrode formed on the photovoltaic stack and including a carbon based layer and a high work function metal layer, the high work function metal layer being disposed at an interface between the carbon based layer and the P-doped layer such that the high work function metal layer forms a reduced barrier contact and is light transmissive.

2. The photovoltaic device as recited in claim 1, wherein carbon based layer includes one of carbon nanotubes and graphene.

3. The photovoltaic device as recited in claim 1, wherein the N-doped layer the intrinsic layer and the P-doped layer include amorphous silicon.

4. The photovoltaic device as recited in claim 1, wherein the reduced barrier contact includes an ohmic contact.

5. The photovoltaic device as recited in claim 1, wherein the device includes a flexible substrate.

6. The photovoltaic device as recited in claim 1, further comprising at least one back-reflector layer coupled to the photovoltaic stack on a side opposite the transparent electrode.

7. The photovoltaic device as recited in claim 1, wherein the high work function metal layer includes one or more of Au, Ag, Pd and Pt.

8. The photovoltaic device as recited in claim 1, wherein the high work function metal layer includes a work function greater than the carbon based layer.

9. The photovoltaic device as recited in claim 1, wherein the high work function metal layer includes a thickness of between about 0.1 nm and about 20 nm.

10. The photovoltaic device as recited in claim 1, wherein the high work function metal layer includes a discontinuous layer of nanodots.

11. A photovoltaic device, comprising:
a photovoltaic stack having a P-type layer, an intrinsic layer and an N-type layer;
a transparent electrode formed on the P-type layer of the photovoltaic stack, the transparent electrode including a conductive carbon based layer and a high work function metal layer, the high work function metal layer being disposed at an interface between the carbon based layer and the P-type layer such that the high work function metal layer forms a reduced barrier contact and is light transmissive; and
a reflective metal substrate disposed in contact with the N-type layer.

12. The photovoltaic device as recited in claim 11, wherein conductive carbon based layer includes one of carbon nanotubes and graphene.

13. The photovoltaic device as recited in claim 11, wherein the P-type layer, the intrinsic layer and the N-type layer include amorphous silicon.

14. The photovoltaic device as recited in claim 11, wherein the reduced barrier contact includes an ohmic contact.

15. The photovoltaic device as recited in claim 11, wherein the high work function metal layer includes one or more of Au, Ag, Pd and Pt.

16. The photovoltaic device as recited in claim 11, wherein the high work function metal layer includes a work function greater than the conductive carbon based layer.

17. The photovoltaic device as recited in claim 11, wherein the high work function metal layer includes a thickness of between about 0.1 nm and about 20 nm.

18. The photovoltaic device as recited in claim 11, wherein the high work function metal layer includes a discontinuous layer.

19. The photovoltaic device as recited in claim 18, wherein the discontinuous layer includes nanodots.

20. A method for forming a photovoltaic device, comprising:
forming a photovoltaic stack on a first electrode, the stack including an N-type layer, an intrinsic layer and a P-type layer;
depositing a high work function metal layer on the photovoltaic stack; and
forming a carbon based layer over the high work function metal layer such that the carbon based layer and the high work function metal layer form a reduced barrier contact that is light transmissive.

21. The method as recited in claim 20, wherein the carbon based layer includes one of carbon nanotubes and graphene.

22. The method as recited in claim 20, wherein the N-type layer, the intrinsic layer and the P-type layer include amorphous silicon.

23. The method as recited in claim 20, wherein the reduced barrier contact includes an ohmic contact.

24. The method as recited in claim 20, wherein the high work function metal layer includes one or more of Au, Ag, Pd and Pt.

25. The method as recited in claim 20, wherein depositing a high work function metal layer includes depositing the high work function metal layer as a discontinuous layer of nanodots.
